(19) United States
(12) Patent Application Publication
(10) Pub. No.: US 2025/0380396 A1
(43) Pub. Date: Dec. 11, 2025

(54) Local Oxidation for Three-Dimensional Dynamic Random Access Memory Transistor

(71) Applicant: Synopsys, Inc., Sunnyvale, CA (US)

(72) Inventors: Meng-Hsuan Ke, Hsinchu City (TW); Salvatore Maria Amoroso, Hamilton (GB); Plamen Asenov Asenov, Glasgow (GB); Xi-Wei Lin, Fremont, CA (US); Ko-Hsin Lee, Zhubei City (TW)

(21) Appl. No.: 18/736,044

(22) Filed: Jun. 6, 2024

(51) Int. Cl. H10B 12/00; G06F 30/31

(52) U.S. Cl. CPC H10B 12/05; G06F 30/31; H10B 12/30

(57) ABSTRACT

A method may include operations associated with providing a stack of layers, the layers separated by a dielectric between the layers, each layer comprising a plurality of unit cells separated by the dielectric between the plurality of unit cells, each unit cell including a silicon channel, a gate oxide surrounding the silicon channel in at least two dimensions, and a gate metal surrounding the gate oxide in the at least two dimensions, the operations including recess etching to remove a portion of the gate metal in each unit cell and applying an oxide growth process to the gate oxide in each unit cell.

### TECHNICAL FIELD

The present disclosure relates to dynamic random access memory (DRAM), and more particularly three-dimensional (3D) DRAM arrays with transistors having gates with rounded corner edge profiles and gate oxides with increased thickness, as well as to methods of forming such arrays.

### BACKGROUND

One type of advanced dynamic random access memory (DRAM) is three-dimensional (3D) DRAM, which includes vertically stacked memory blocks, which may provide substantially increased memory density per chip. The fabrication of a vertically integrated 1-transistor 1-capacitor (1T1C) DRAM cell may be realized by placing several access transistors and the associated storage capacitors in a same horizontal layer, and then vertically stacking multiple layers.

### BRIEF DESCRIPTION OF THE DRAWINGS

Thepresent disclosure will be understood more fully from the detailed description given below and from the accompanying figures of embodiments of the present disclosure. The figures are used to provide knowledge and understanding of embodiments of the present disclosure and do not limit the scope of the present disclosure to these specific embodiments. Furthermore, the figures are not necessarily drawn to scale.

FIG. 1 illustrates aspects of an example process for forming a 3D DRAM array in accordance with the present disclosure.

FIG. 2 illustrates additional aspects of an example process for forming a 3D DRAM array in accordance with the present disclosure.

FIG. 3 illustrates further aspects of an example process for forming a 3D DRAM array in accordance with the present disclosure.

FIG. 4 illustrates example views of a gate-all-around (GAA) transistor with rounded corner edge profile, in accordance with the present disclosure.

FIG. 5 illustrates an example block at an intermediate stage of a 3D DRAM fabrication process, in accordance with the present disclosure.

FIG. 6 illustrates a flowchart of an example method for forming an integrated circuit (e.g., a 3D DRAM), in accordance with the present disclosure.

FIG. 7 illustrates a flowchart of various processes used during the design and manufacture of an integrated circuit in accordance with some embodiments of the present disclosure.

FIG. 8 illustrates a diagram of an example computer system in which embodiments of the present disclosure may operate.

### DETAILED DESCRIPTION

Aspects of the present disclosure relate to the production of three-dimensional (3D) dynamic random access memory (DRAM). In particular, 3D DRAM may include vertically stacked memory blocks, which may provide substantially increased memory density per chip. The fabrication of a vertically integrated 1-transistor/1-capacitor (1T1C) DRAM cell may be realized by placing several access transistors and the associated storage capacitors in a same horizontal layer, and then vertically stacking multiple layers. The vertical scaling may permit the cells’ feature sizes to be relaxed, thereby reducing short-channel related effects and reliability issues, while still increasing the memory density per chip. In particular, the vertical integration of multiple layers of metal/insulator/semiconductor materials imposes the adoption of thin semiconductor layers to form the channel of the access transistor, which may relate to two primary reasons: (1) the large mechanical stress induced by the crystalline mismatch between materials used in the initial multi-layering steps (predominantly silicon and sacrificial silicon germanium), and (2) the electrostatic control of the channel, which for thick channel layers may see the insurgence of deleterious effects such as the floating body effect and increased source-to-drain leakage current. On the other hand, thin semiconductor channels may suffer from strong electric field-enhanced off-state leakage due to the high electric field induced by the gate corners onto the channel regions next to the source and drain.

Examples of the present disclosure introduce local oxidation in 1T1C DRAM fabrication to create a rounded gate edge profile, which may reduce the gate-induced off-state electric field in the channel-drain and channel-source junctions, and by consequence, reduce the off-state band-to-band leakage current and increase the retention time of the DRAM cells. In one example, local oxidation of the gate oxide of the gate-all-around transistor during transistor spacer formation increases the oxide thickness towards the source and drain ends of the channel. Notably, increasing the oxide thickness just towards the channel ends reduces the gate-to-drain electric field in these channel regions, e.g., as compared to no oxide growth process step and/or as compared to less thickness. At the same time, a rounding of the gate edge may be provided to lower the electric field due to corner effects. Thus, examples of the present disclosure achieve vertically stacked gate-all-around transistors for 1T1C vertically stacked 3D DRAM arrays featuring non-uniform gate-oxide geometries with increased oxide thickness at the channel ends and/or rounded corner edge profiles.

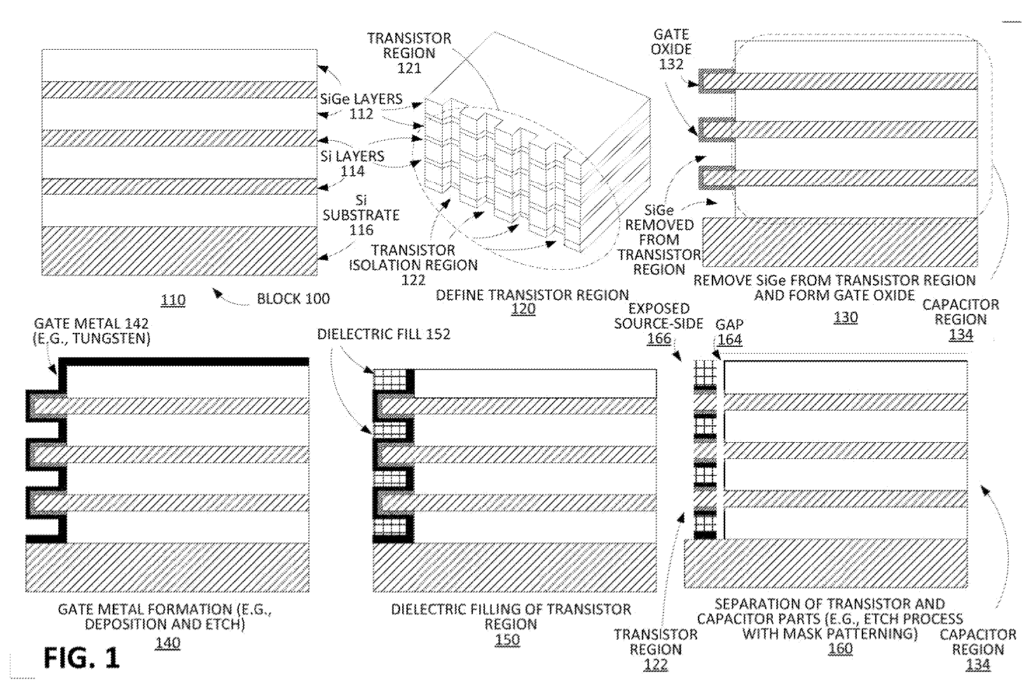

Technical advantages of the present disclosure include, but are not limited to, reduced off-state field-enhanced band-to-band leakage and improved DRAM retention time, e.g., for gate-all-around transistors in 1T1C vertically stacked 3D DRAM arrays. In addition, fabrication methods for 3D DRAM arrays are improved through the addition of a local oxidation step and/or corner edge profiling as described herein to provide such a 3D DRAM array with transistors having non-uniform gate-oxide geometries. These and other aspects of the present disclosure are discussed in greater detail below in connection with the examples of FIGS. 1-8.

FIG. 1 illustrates aspects of an example process for forming a 3D DRAM array in accordance with the present disclosure. For instance, a first stage 110 may begin with a multilayer stacking of Silicon-Germanium (SiGe) layers 112 and Silicon (Si) layers 114 on a Si substrate/base 116 to form a block 100. In stage 120, the block 100 may be etched to define a transistor isolation region 122 (which may also be referred to as the active region), e.g., using a hard mask. In stage 130, portions of the SiGe layers 112 may be removed from the transistor isolation region 122. Other portions of the SiGe layers 112 in the capacitor region 134 may be protected by hard mask (HM) patterning. In one example, the silicon edge of Si layers 114 in the transistor isolation region 122 may be rounded (or given a rounded edge profile), which may lower the electric field due to corner effects. In addition, stage 130 may include a deposition of gate oxide 132 around the portions of the Si layers 114 in the transistor isolation region 122. For instance, the gate oxide may be silicon dioxide (SiO₂). In stage 140, a gate metal 142 may be deposited on the interface. For instance, stage 140 may include several loops of deposition and isotropic etching to connect the gate metal 142, e.g., tungsten (W), in a horizontal plane. Stage 150 may include dielectric filling of the transistor isolation region 122 with dielectric fill 152. In one example, stage 150 may also include a chemical mechanical planarization (CMP) process. At this point, the transistor material is completely formed.

Stage 160 may include separation of the transistor isolation region 122 (also referred to herein as the transistor region) and the capacitor region 134 to define a gap 164. For instance, in one example, stage 160 may include an etch process with mask patterning, e.g., photolithography. In one example, the etch process and mask patterning may remove materials on the source-side and drain-side of the transistor channel (e.g., exposed source-side 166 and a drain-side opposite the source-side 166 across the gap 164). It should also be noted that the etch process with mask patterning of stage 160 may leave the gate metal 142 interconnected across transistors/gates in the horizontal direction, but in the vertical direction, it is separated. For instance, in one example, this configuration supports the routing of a shared word line (WL) horizontally. It should be noted that a shared bit line (BL) may be added for each column vertically in a later stage.

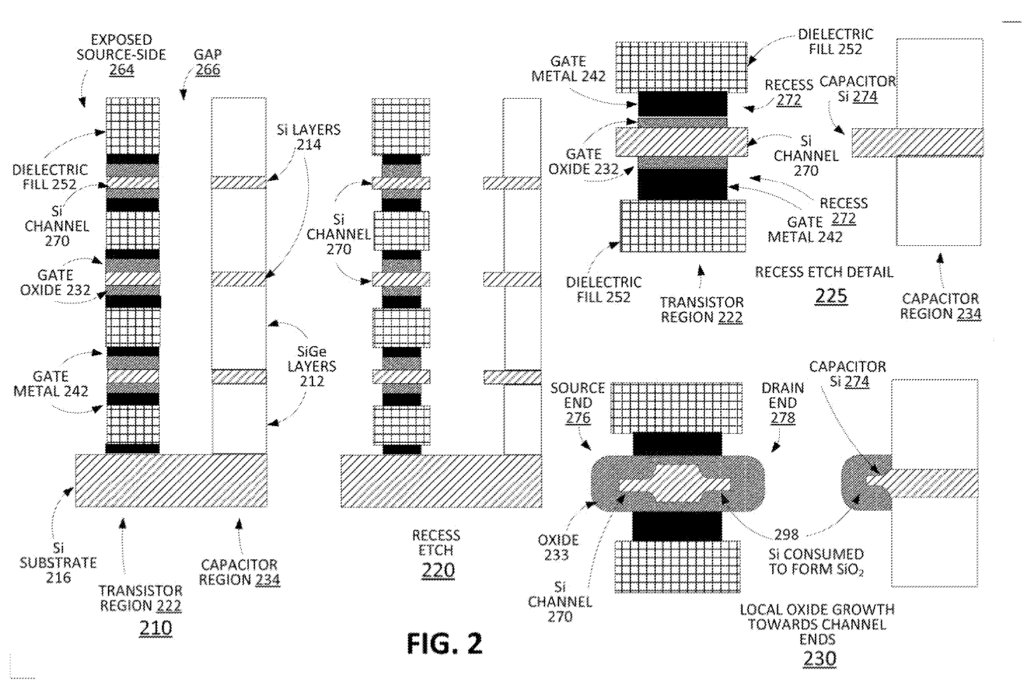

FIG. 2 illustrates additional aspects of an example process for forming a 3D DRAM array in accordance with the present disclosure. In particular, FIG. 2 illustrates a portion of a block having a Silicon (Si) substrate 216, a transistor region 222, and a part of capacitor region 234 at a stage 210, e.g., an intermediate stage in the formation of a 3D DRAM array. For instance, stage 210 may be the same or similar to stage 160 of FIG. 1. Likewise, block components illustrated in stage 210 may be the same or similar to counterparts as illustrated in FIG. 1 (e.g., SiGe layers 212, Si layers 214, dielectric fill 252, gate oxide 232 and gate metal 242, etc.). It should be noted that for illustrative purposes, only a small portion of the capacitor region 234 is shown in FIG. 2. For instance, an actual length of the capacitor region may be substantially larger than the transistor region. As illustrated in FIG. 2 at stage 210, a portion of the Si layers 214 may define a silicon (Si) channel 270 (e.g., where there may be multiple instance of Si channel 270 in an array). In stage 210, the Si channel(s) 270 have an exposed source side 264 and an exposed drain side (e.g., gap 266 between the transistor region 222 and the capacitor region 234).

In accordance with the present disclosure, at stage 220 a recess etch may be applied to recess the gate metal 242 and gate oxide 232 to expose a portion of the silicon channel 270 on both the source side (e.g., exposed source side 264) and the drain side (e.g., gap 266). In one example, the recess etch may comprise an isotropic etch. It should be noted that the exposed portions of the silicon channel 270 may define the active region(s) for local oxide growth at the next stage 230. View 225 provides a more detailed view of the result of the recess etching of stage 220. For instance, recesses 272 may be defined around the Si channel 270 on both ends (e.g., both the source and drain sides) via removal of portions of the gate metal 242 and gate oxide 232 partially surrounding the Si channel 270. It should also be noted that as illustrated in view 225, the recess etch may also remove some of the SiGe layer(s) 212 in the capacitor region 234 to provide exposed capacitor silicon (Si) 274 (e.g., the end(s) of the Si layer(s) 214 closest to the transistor region 222).

A next stage 230 includes local oxide growth around the silicon ends, e.g., source end 276 and drain end 278 of Si channel 270. In particular, stage 230 may include thermal oxide growth, which increases oxide thickness towards the channel ends (e.g., source end 276 and drain end 278). Notably, the increased thickness may provide a reduction in the gate-induced electric field in the source/drain regions. It should be noted that the oxide deposition process may also consume portions of the silicon 298, e.g., from Si channel 270, as well as from the exposed capacitor Si 274. In particular, some of the Si may be consumed to form SiO₂, e.g., oxide 233.

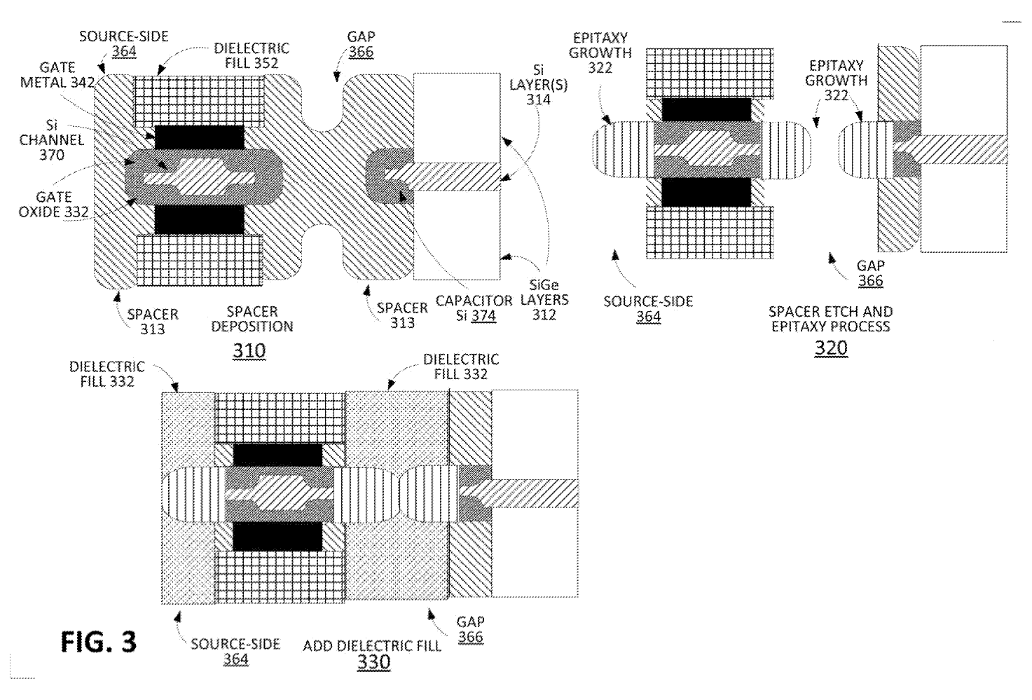

FIG. 3 illustrates further aspects of an example process for forming a 3D DRAM array in accordance with the present disclosure. For instance, in one example, stage 310 of FIG. 3 may follow stage 230 of FIG. 2. In this regard, block components illustrated in stage 310 may be the same or similar to counterparts as illustrated in FIG. 2 (e.g., SiGe layers 312, Si layers 314, dielectric fill 352, gate oxide 332, gate metal 342, Si channel 370, etc.). As shown in FIG. 3, stage 310 may include a deposition of spacer 313 on the source and drain sides (e.g., on source side 364 and within gap 366). The next stage 320 may include a recess etch of the spacer 313 to expose the silicon in the transistor region (e.g., Si channel 370) and the capacitor region (e.g., the end of Si layer 314 closest to the transistor region). In addition, stage 320 may include an epitaxy process to form epitaxy growth 322 at the exposed ends of the silicon. The result of the epitaxy process is a joining of the epitaxy growth 322 to link the transistor side and capacitor side as shown in stage 330. In addition, stage 330 may include a dielectric fill process where dielectric fill 332 is added between the transistor region and capacitor region, as well as on the source side of the transistor region. In one example, stage 330 may also include application of a chemical mechanical planarization (CMP) process. It should be noted that in various examples, the spacer 313, dielectric fill 352, and dielectric fill 332 may be the same type of material or may comprise different materials.

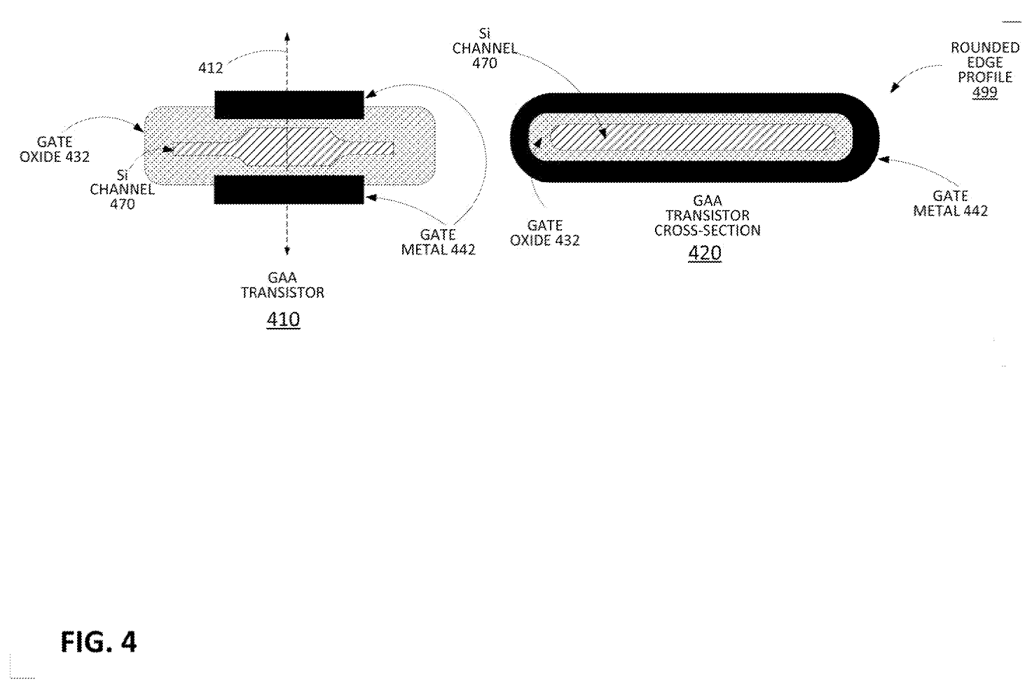

FIG. 4 illustrates an example gate-all-around (GAA) transistor 410, having a silicon (Si) channel 470, a gate oxide 432 surrounding the Si channel 470, and a gate metal 442 surrounding the gate oxide 432 in two dimensions. As shown in FIG. 4, the Si channel 470 may include tapered ends, e.g., where some of the Si channel 470 has been consumed in forming the gate oxide 432. FIG. 4 further includes a cross-section view 420 of the GAA transistor 410, e.g., where the cross section is taken from a plane defined by 412 through the middle of GAA transistor 410, and where the rounded corner edge profile 499 is visible. It should also be noted that the foregoing description as well as the illustrations of FIGS. 1-4 are provided by way of example only, and that other, further, and different examples of the present disclosure may include a different process or variations of the above described and illustrated process(es) of FIGS. 1-4. For instance, a different sequence of stages, or operations within the stages, may be followed to define a transistor isolation region 122 having an array of transistors/transistor precursors such as illustrated in stage 160. In addition, stage 120 illustrates that a three-by-three array of nine transistors (and hence nine memory cells) is to be formed (e.g., with the left-most and right-most extensions being reserved/used for a staircase write-line area). However, other, further, and different examples may include arrays with more or less transistors and/or 1T1C memory units. Likewise, other aspects of the present figures are not necessarily drawn to scale with relation to one another. For instance, the gate oxide 232 may be a layer with smaller thickness than the Si channel 270, and so forth.

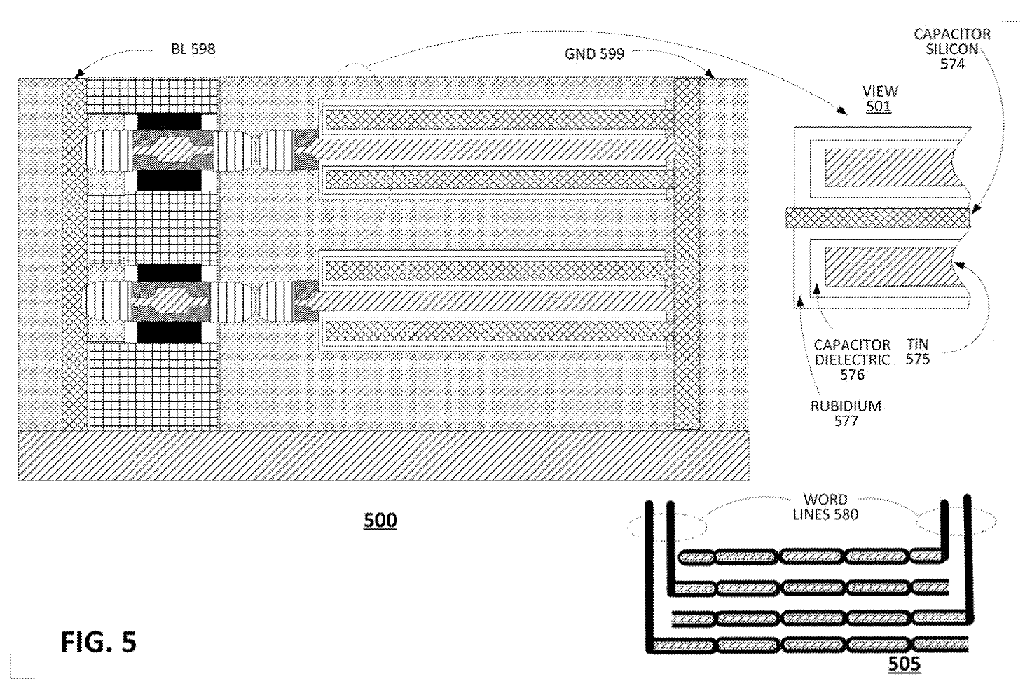

In one example, stage 330 may be followed by various operations to form an array of capacitors in a capacitor region. For instance, the 3D DRAM fabrication may continue with: removing SiGe layers in the capacitor region, e.g., via photo mask patterning to define different rows of the capacitor region, applying sacrificial film and nitride, removing the sacrificial film, and depositing capacitor films, e.g., ruthenium, a dielectric and titanium nitride (TiN). After the capacitor film formation, the 3D DRAM fabrication process may continue with etching ground section recesses, e.g., using a photo mask to define the pattern for ground recesses, and then filling with titanium nitride, which forms a capacitor ground. In addition, the 3D DRAM fabrication process may further include forming bit lines in a vertical bit-line (BL) arrangement and write lines in a staircase write line (WL). For instance, FIG. 5 illustrates an example block 500 (e.g., which may be the same or similar to block 100 of FIG. 1, but at a later stage in a 3D DRAM fabrication process). In particular, block 500 includes a bit line (BL) 598 and ground connection (GND) 599. It should be noted that insofar as the view of block 500 may represent a cross-section, there may be multiple parallel bit lines and/or ground connections for adjacent 1T1C unit cells. View 501 illustrates a more detailed view of a portion of one of the capacitor regions of block 500, e.g., including capacitor silicon 574, which may be formed as titanium silicide (TiSiₓ), two parallel strips of titanium nitride 575 surrounded by capacitor dielectric 576, and two regions of ruthenium film 577 surrounding the capacitor dielectric 576. An additional view 505 illustrates a cross-section of block 500 from a different perspective, e.g., rotated 90 degrees, which shows word lines 580 in a WL ladder arrangement. In the view 505, there are 12 transistors (and hence twelve 1T1C unit cells) in a four-by-three array, with the left-most and right-most regions being reserved for WL connections. Thus, these and other aspects are all contemplated within the scope of the present disclosure.

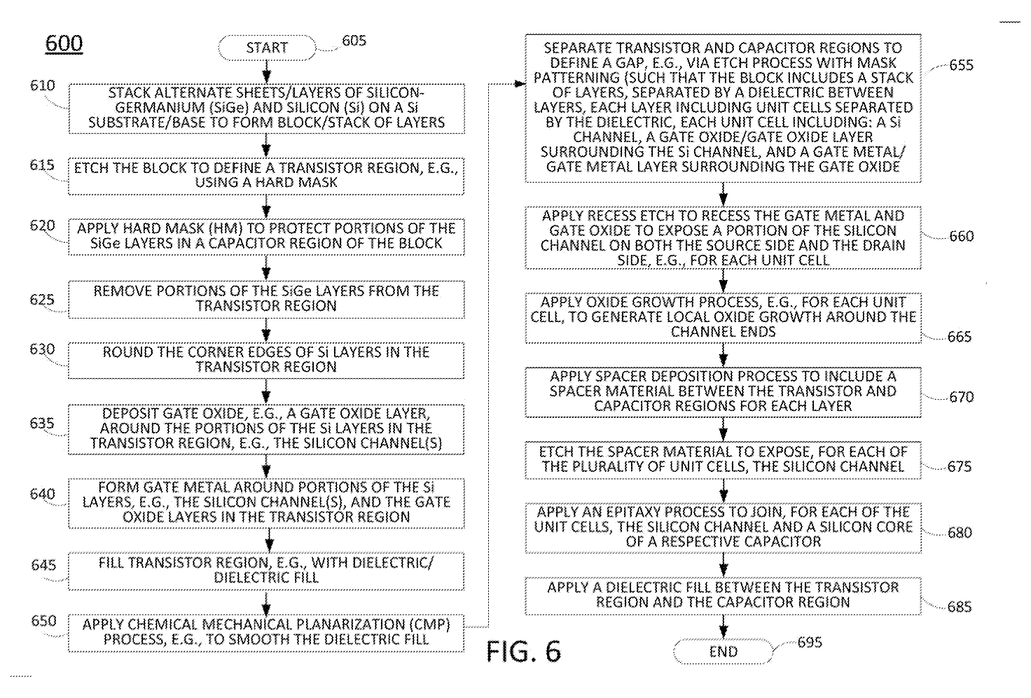

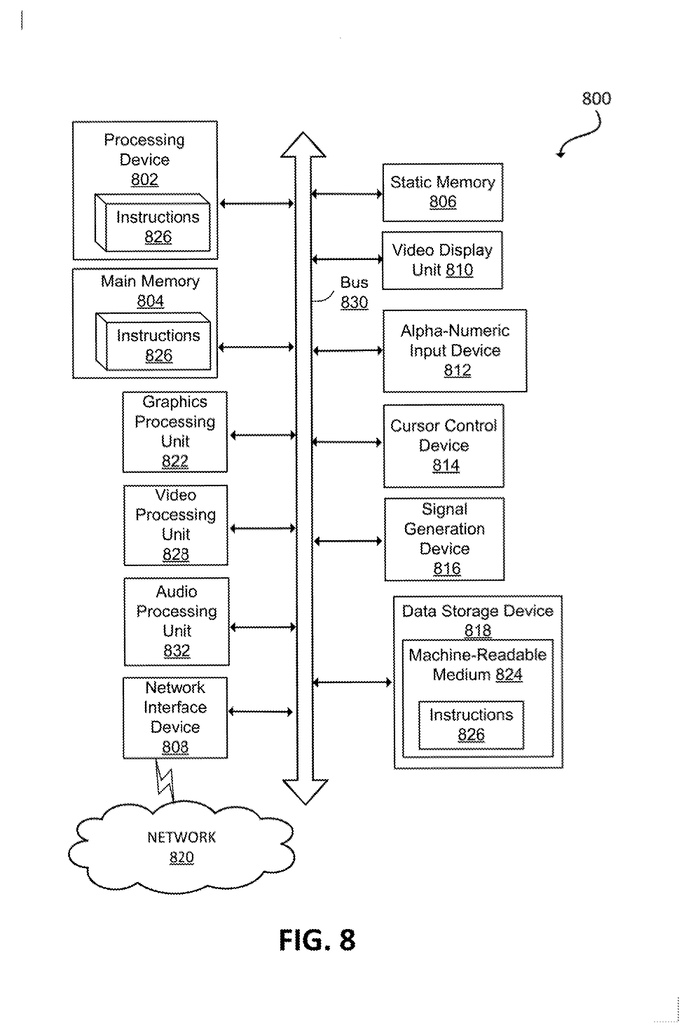

FIG. 6 illustrates a flowchart of an example method 600 for forming an integrated circuit (e.g., a 3D DRAM). In one example, the method 600 may be performed by a computing device or system, e.g., a processing system, or processing device, including at least one processor, a memory storing instructions, which when executed by the at least one processor, cause the processing system to perform operations, etc. For instance, the method 600 may be performed by a processing system including at least one processor, such as the computer system 800 of FIG. 8, and/or any one or more components thereof, such as processing device 802, or multiple instances of computer system 800 in communication over one or more networks and operating collectively to perform one or more aspects of the method 600. In one example, one or multiple instances of the computer system 800 may provide automated control of lithography equipment, chemical vapor deposition (CVD) equipment, plasma etching equipment, ion-implantation equipment, robotics and assembly line equipment, and so forth. In one example, one or multiple instances of the computer system 800 may perform aspects of the example method 400 in connection with a technology computer-aided design (TCAD) process simulation. For example, aspects of the method 400 may be performed as a process simulation to virtually model a semiconductor device fabrication process. The method 600 begins in 605 and may proceed to 610.

At 610, the method 600 may include stacking alternate sheets (or layers) of Silicon-Germanium (SiGe) and Silicon (Si) on a Si substrate/base, e.g., to form a stack of layers, or a block. For instance, each layer in the block may comprise one sheet of SiGe and one sheet of Si. For instance, 610 may result in a block such as illustrated in stage 110 of FIG. 1 and described above. At 615, the method 600 may include etching the block to define a transistor isolation region (which may also be referred to as the active region or the transistor region), e.g., using a hard mask. For instance, 615 may include operations such as illustrated in stage 120 of FIG. 1 and described above.

At 620, the method 600 may include applying a hard mask (HM) to protect portions of the SiGe layers in a capacitor region of the block. At 625, the method 600 may include removing portions of the SiGe layers from the transistor region.

At 630, the method 600 may include rounding the corner edges of Si layers in the transistor region. For instance, the portions of the Si layers in the transistor region, which may also be referred to as a silicon channel, may be given a rounded edge profile. When a transistor is fully formed and in operation, this may lower the electric field due to corner effects. In various examples, 630 may include one or more of: a hydrogen annealing and wet oxide pull-back process, or a linear oxidation process.

At 635, the method 600 may include deposition of a gate oxide, e.g., a gate oxide layer, around the Si layers in the transistor region, e.g., the silicon channel(s). For instance, the gate oxide may be silicon dioxide (SiO₂). It should be noted that aspects of 620-635, may include operations such as illustrated in stage 130 of FIG. 1 and described above.

At 640, a gate metal may be formed along with the interface including the transistor region and the capacitor region, e.g., the silicon channel(s). In one example, the gate metal may surround the gate oxide layers in the transistor region in at least two dimensions. For instance, 640 may include several loops of deposition and isotropic etching, e.g., in order to connect the writeline (WL) horizontally. In one example, the gate metal may be tungsten (W), e.g., a tungsten layer. In one example, 640 may include operations such as illustrated in stage 140 of FIG. 1 and described above.

At 645, the method 600 may include filling of the transistor region, e.g., with dielectric/dielectric fill, e.g., a dielectric material with a small relative dielectric constant, or a low-K dielectric. At 650, the method 600 may also include a chemical mechanical planarization (CMP) process, e.g., to smooth the dielectric fill. It should be noted that aspects of 645-650, may include operations such as illustrated in stage 150 of FIG. 1 and described above.

At 655, the method 600 may include separating of the transistor region and the capacitor region to define a gap. For instance, in one example, 655 may include an etch process with mask patterning, e.g., photolithography. In one example, the etch process and mask patterning may further remove materials on the source-side of the transistor channel (e.g., a transistor source-side) as well as on the drain-side. It should also be noted that the etch process with mask patterning of stage 655 may leave the gate metal interconnected across transistors/gates in the horizontal direction, but in the vertical direction, it may be separated. For instance, this configuration may support the routing of a shared word line (WL) horizontally. It should be noted that a shared bit line (BL) may subsequently be added for each column vertically. Notably, a portion of the Si layers may define a silicon channel, e.g., multiple instances of a silicon channel in an array of unit cells, with an exposed source side and an exposed drain side, e.g., a gap between the transistor region and capacitor region. In one example, 655 may include operations such as illustrated in stage 160 of FIG. 1 and/or stage 210 of FIG. 2 and described above.

Thus, in one example, the method 600 may include providing a stack of layers, the layers separated by a dielectric between layers, each layer comprising a plurality of unit cells separated by the dielectric between the unit cells, and each unit cell including: a silicon channel, a gate oxide (or gate oxide layer) surrounding the silicon channel in at least two dimensions, e.g., to form a gate-all-around oxide, and a gate metal (or gate metal layer) surrounding the gate oxide in the at least two dimensions, e.g., to form a gate-all-around metal. For example, providing the stack of layers may include any or all of the above from 610-655. For instance, providing the stack of layers may include etching the block at 615, applying the hard mask at 620, removing portions of SiGe at 625, depositing the gate oxide at 635, and/or forming the gate metal at 640, etc. It should be noted that the at least two dimensions may be two dimensions of a cross-section of a unit cell in a transistor source-to-drain/drain-to-source direction (e.g., where the transistor source-to-drain/drain-to-source direction is normal with respect to the plane defined by the two dimensions of the cross-section). For instance, the gate oxide may surround the silicon channel in an X and Y direction, while in the Z direction the silicon channel ends may be exposed. In this regard, it should be further noted that the silicon channel may have a source side and a drain side, e.g., channel ends, where the drain side is closest to the capacitor region. In one example, each unit cell may comprise a precursor to a respective transistor of a plurality of transistors, e.g., a plurality of gate-all-around (GAA) transistors. In one example, each layer of the stack of layers may further include a capacitor region for forming a plurality of capacitors, each capacitor associated with a respective unit cell of the plurality of unit cells, e.g., each unit cell including a respective capacitor of the plurality of capacitors. As described above, the stack of layers may be for forming a 3D DRAM array.

At 660, the method 600 may apply a recess etch to recess the gate metal and gate oxide to expose a portion of the silicon channel on both the source side and the drain side, e.g., for each unit cell. In one example, the recess etching of 660 may define a transistor gate length. In one example, the recess etch may comprise an isotropic etch. It should be noted that the exposed portions of the silicon channel may define the active region(s) for subsequent local oxide growth at 665. It should also be noted that the recess etch of 660 may also remove some of the SiGe layer(s) in the capacitor region to provide exposed capacitor Si, e.g., the end(s) of the Si layer(s) closest to the transistor region, such as illustrated in stage 220 of FIG. 2.

At 665, the method 600 may apply an oxide growth process to the active region, e.g., silicon exposed at the end of the channel, e.g., for each unit cell, to generate local oxide growth around the channel ends of the silicon channel (e.g., a source end and a drain end of the Si channel(s)). In particular, 665 may include thermal oxide growth, which increases oxide thickness towards the channel ends. Notably, the increased thickness may provide a reduction in the gate-induced electric field in the source/drain regions, e.g., as compared to a lesser thickness and/or as compared to no local oxide growth such as provided at 655. It should be noted that the oxide growth process may also consume portions of the silicon, e.g., from Si channel(s) at the channel ends, to grow the gate oxide (as well as from the exposed capacitor-region Si). In particular, some of the Si may be consumed to form SiO₂ of the gate oxide. In one example, the oxide growth process provides a rounding of a gate edge profile, which may also reduce the electric field due to corner effects. The overall effect of thickened gate oxide and/or rounded corners of the silicon channel and gate oxide at the channel ends is a reduction in off-state field-enhanced band-to-band leakage and improved DRAM retention time. In one example, 665 may include operations such as illustrated in stage 230 of FIG. 2 and described above.

At 670, the method 600 may include applying a spacer deposition process to include a spacer material between the transistor region and the capacitor region for each layer of the stack of layers (and, in one example, to also to deposit the spacer material on the outside/source edge of the transistor region). For instance, 670 may include operations such as illustrated in stage 310 of FIG. 3 and described above. In one example, the spacer material may be a dielectric nitride compound.

At 675, the method 600 may include etching the spacer material to expose, for each of the plurality of unit cells, the silicon channel. For instance, 675 may include operations such as illustrated in stage 320 of FIG. 3 and described above.

At 680, the method 600 may include applying an epitaxy process to join, for each of the plurality of unit cells, the silicon channel and a silicon core of a respective capacitor of the plurality of capacitors (e.g., the exposed capacitor-region Si). For instance, 680 may include operations such as illustrated in stage 320 and or stage 330 of FIG. 3 and described above. In one example, the epitaxy process may grow doped silicon (e.g., phosphorus-doped (P-doped) silicon) on exposed source and drain edges of the silicon channel and on the exposed silicon in the capacitor region, but not on other regions (however, it should be noted that doped silicon may also grow on any SiGe that may be exposed).

At 685, the method 600 may include applying a dielectric fill between the transistor region and the capacitor region, e.g., and surrounding an epitaxy growth of the epitaxy process for each unit cell. For instance, 685 may include operations such as illustrated in stage 330 of FIG. 3 and described above. Following 685, the method 600 may proceed to 695 where the method 600 ends.

It should be noted that method 600 may be expanded to include additional steps, or may be modified to replace steps with different steps, to combine steps, to omit steps, to perform steps in a different order, and so forth. In one example, the method 600 may be expanded or modified to include steps, functions, and/or operations, or other features described in connection with the example(s) of FIGS. 1-5, 7, and/or 8, or as described elsewhere herein. For example, the method 600 may be expanded to include operations such as described above to form capacitors for each unit cell in the capacitor region. Thus, these and other modifications are all contemplated within the scope of the present disclosure.

Accordingly, in one example, a method may include operations associated with providing a stack of layers, the layers separated by a dielectric between the layers, each layer comprising a plurality of unit cells separated by the dielectric between the plurality of unit cells, each unit cell including a silicon channel, a gate oxide surrounding the silicon channel in at least two dimensions, and a gate metal surrounding the gate oxide in the at least two dimensions, the operations including recess etching to remove a portion of the gate metal in each unit cell and applying an oxide growth process to the channel ends, e.g., source-side and drain-side in each unit cell.

In addition, in one example, the present disclosure may include an apparatus having a plurality of transistors, each transistor including: a silicon channel, where the silicon channel includes a rounded corner edge profile, a gate oxide surrounding the silicon channel, and a gate metal surrounding the gate oxide in at least two dimensions. In one example, the plurality of transistors may be arranged in a stack of layers. In addition, in one example, the apparatus may further include a dielectric between the plurality of transistors in each layer of the stack of layers and between each layer.

Alternatively, or in addition, in one example, the present disclosure may include an apparatus having a stack of layers, the layers separated by a dielectric between the layers, and each layer comprising a plurality of unit cells separated by the dielectric between the plurality of unit cells. In one example, each unit cell may include: a silicon channel, where the silicon channel includes a rounded corner edge profile, a gate oxide surrounding the silicon channel, and a gate metal surrounding the gate oxide in at least two dimensions.

In another example, the present disclosure may include an apparatus having a plurality of transistors, each transistor including: a silicon channel, a gate oxide surrounding the silicon channel, where a thickness of the gate oxide at a channel end reduces a gate-to-drain electric field, e.g., as compared to no oxide growth process step and/or as compared to less thickness, and a gate metal surrounding the gate oxide in at least two dimensions. In one example, the plurality of transistors may be arranged in a stack of layers, with a dielectric between the plurality of transistors in each layer of the stack of layers and between each layer of the stack of layers. In one example, the silicon channel may also include a rounded corner edge profile.

In still another example, the present disclosure may include an apparatus having a stack of layers, the layers separated by a dielectric between the layers, each layer comprising a plurality of unit cells separated by the dielectric between the plurality of unit cells. In one example, each unit cell may include: a silicon channel, a gate oxide surrounding the silicon channel, where a thickness of the gate oxide at a channel end reduces a gate-to-drain electric field, e.g., as compared to no local oxide growth process step and/or as compared to less thickness, and a gate metal surrounding the gate oxide in at least two dimensions. In one example, the silicon channel may also include a rounded corner edge profile. In one example, any or all of the foregoing apparatus(es) may be produced via the example method 600 of FIG. 6.

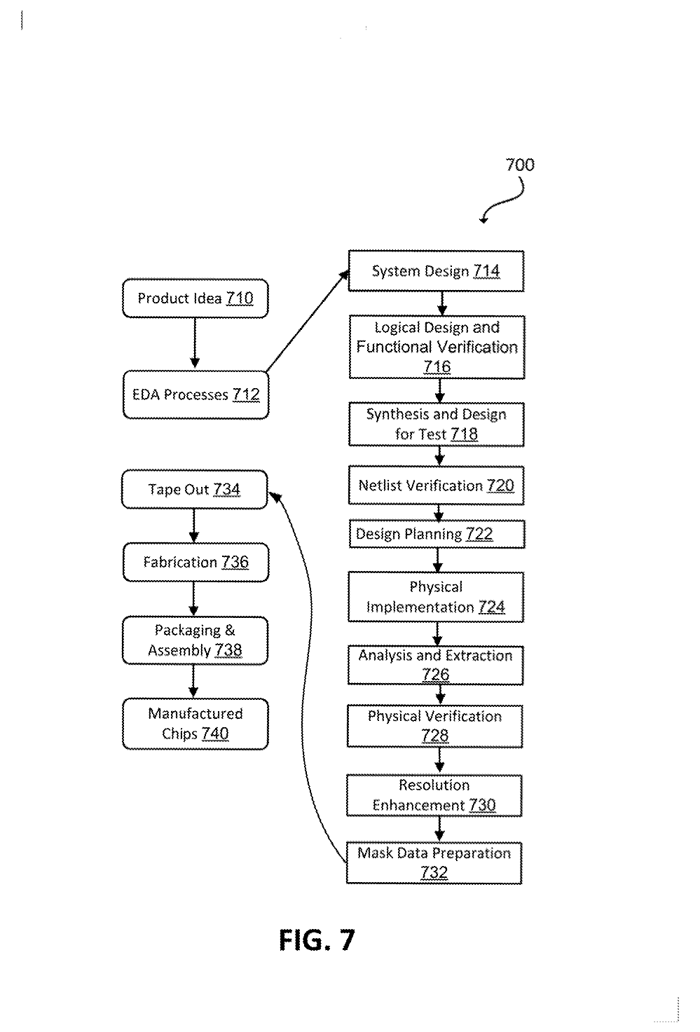

FIG. 7 illustrates an example set of processes 700 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 710 with information supplied by a designer, information which is transformed to create an article of manufacture that uses a set of EDA processes 712. When the design is finalized, the design is taped-out 734, which is when artwork (e.g., geometric patterns) for the integrated circuit is sent to a fabrication facility to manufacture the mask set, which is then used to manufacture the integrated circuit. After tape-out, a semiconductor die is fabricated 736 and packaging and assembly processes 738 are performed to produce the finished integrated circuit 740.

Specifications for a circuit or electronic structure may range from low-level transistor material layouts to high-level description languages. A high-level of representation may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful details into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding systems of that layer (e.g., a formal verification system). A design process may use a sequence depicted in FIG. 7. The described processes may be enabled by EDA products (or EDA systems).

During system design 714, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 716, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 718, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 720, the netlist is checked for compliance with timing constraints and for correspondence with the HDL code. During design planning 722, an overall floor plan for the integrated circuit is constructed and analyzed for timing and top-level routing.

During layout or physical implementation 724, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 726, the circuit function is verified at the layout level, which permits refinement of the layout design. During physical verification 728, the layout design is checked to ensure that manufacturing constraints are correct, such as DRC constraints, electrical constraints, lithographic constraints, and that circuitry function matches the HDL design specification. During resolution enhancement 730, the geometry of the layout is transformed to improve how the circuit design is manufactured.

During tape-out, data is created to be used (after lithographic enhancements are applied if appropriate) for production of lithography masks. During mask data preparation 732, the ‘tape-out’ data is used to produce lithography masks that are used to produce finished integrated circuits.

A storage subsystem of a computer system (such as computer system 800 of FIG. 8) may be used to store the programs and data structures that are used by some or all of the EDA products described herein, and products used for development of cells for the library and for physical and logical design that use the library.

FIG. 8 illustrates an example machine of a computer system 800 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term "machine" shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM), a static memory 806 (e.g., flash memory, static random access memory (SRAM), etc.), and a data storage device 818, which communicate with each other via a bus 830.

Processing device 802 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 may be configured to execute instructions 826 for performing the operations and steps described herein.

The computer system 800 may further include a network interface device 808 to communicate over the network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), a graphics processing unit 822, a signal generation device 816 (e.g., a speaker), graphics processing unit 822, video processing unit 828, and audio processing unit 832.

The data storage device 818 may include a machine-readable storage medium 824 (also known as a non-transitory computer-readable medium) on which is stored one or more sets of instructions 826 or software embodying any one or more of the methodologies or functions described herein. The instructions 826 may also reside, completely or at least partially, within the main memory 804 and/or within the processing device 802 during execution thereof by the computer system 800, the main memory 804 and the processing device 802 also constituting machine-readable storage media.

In some implementations, the instructions 826 include instructions to implement functionality corresponding to the present disclosure. While the machine-readable storage medium 824 is shown in an example implementation to be a single medium, the term "machine-readable storage medium" should be taken to include a single medium or multiple media (e.g., a centralized or distributed database, and/or associated caches and servers) that store the one or more sets of instructions. The term "machine-readable storage medium" shall also be taken to include any medium that is capable of storing or encoding a set of instructions for execution by the machine and that cause the machine and the processing device 802 to perform any one or more of the methodologies of the present disclosure. The term "machine-readable storage medium" shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each connected to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory ("ROM"), random access memory ("RAM"), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The present disclosure and drawings are, accordingly, to be regarded in an illustrative sense rather than a restrictive sense.

What is claimed is:

1. A method comprising:
providing a stack of layers, the layers separated by a dielectric between the layers, each layer comprising a plurality of unit cells separated by the dielectric between the plurality of unit cells, each unit cell comprising:
a silicon channel;
a gate oxide surrounding the silicon channel in at least two dimensions; and
a gate metal surrounding the gate oxide in the at least two dimensions;
recess etching to remove a portion of the gate metal in each unit cell; and
applying an oxide growth process to the gate oxide in each unit cell.

2. The method of claim 1, wherein the recess etching defines a transistor gate length.

3. The method of claim 2, wherein each unit cell comprises a precursor to a respective transistor of a plurality of transistors.

4. The method of claim 3, wherein the plurality of transistors comprises a plurality of gate-all-around transistors.

5. The method of claim 1, wherein each layer of the stack of layers further includes a capacitor region for forming a plurality of capacitors, each capacitor of the plurality of capacitors associated with a respective unit cell of the plurality of unit cells.

6. The method of claim 1, wherein the stack of layers is for forming a three-dimensional dynamic random access memory array.

7. The method of claim 5, further comprising:
applying, prior to the recess etching, an etch process with mask patterning to separate a transistor region comprising the plurality of unit cells from the capacitor region for each layer of the stack of layers.

8. The method of claim 7, further comprising:
applying a spacer deposition process to include a spacer material between the transistor region and the capacitor region for each layer of the stack of layers;
etching the spacer material to expose, for each of the plurality of unit cells, the silicon channel; and
applying an epitaxy process to join, for each of the plurality of unit cells, the silicon channel and a silicon core of a respective capacitor of the plurality of capacitors.

9. The method of claim 1, wherein for each unit cell, the oxide growth process grows the gate oxide at channel ends of the silicon channel.

10. The method of claim 9, wherein for each unit cell, the oxide growth process consumes a portion of the silicon channel at the channel ends of the silicon channel to grow to the gate oxide at the channel ends of the silicon channel.

11. The method of claim 10, wherein a thickness of the gate oxide at the channel ends reduces a gate-to-drain electric field.

12. The method of claim 1, wherein the oxide growth process provides a rounding of a gate edge profile.

13. The method of claim 1, wherein the silicon channel includes a rounded corner edge profile.

14. The method of claim 13, further comprising:
rounding corner edges of the silicon channel to produce the rounded corner edge profile.

15. The method of claim 14, wherein the rounding of the corner edges comprises at least one of:
a hydrogen annealing and wet oxide pull-back process; or
a linear oxidation process.

16. The method of claim 1, wherein the gate oxide comprises a silicon oxide layer.

17. The method of claim 1, wherein the gate metal comprises a tungsten layer.

18. The method of claim 1, wherein the dielectric comprises a low-k dielectric.

19. An apparatus comprising:
a stack of layers, the layers separated by a dielectric between the layers, each layer comprising a plurality of unit cells separated by the dielectric between the plurality of unit cells, each unit cell comprising:
a silicon channel, wherein the silicon channel includes a rounded corner edge profile;
a gate oxide surrounding the silicon channel; and
a gate metal surrounding the gate oxide in at least two dimensions.

20. An apparatus comprising:
a plurality of transistors, each transistor comprising:
a silicon channel, wherein the silicon channel includes a rounded corner edge profile;
a gate oxide surrounding the silicon channel; and
a gate metal surrounding the gate oxide in at least two dimensions, wherein the plurality of transistors is arranged in a stack of layers; and
a dielectric between the plurality of transistors in each layer of the stack of layers and between each layer of the stack of layers.
